(19) United States
(12) Patent Application Publication
(10) Pub. No.: US 2026/0060112 A1
(43) Pub. Date: Feb. 26, 2026

(54) PANEL-LEVEL SEMICONDUCTOR PACKAGE STRUCTURE AND METHOD FOR MANUFACTURING THEREOF

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW); WEI YEN, TAIPEI CITY (TW); CHIH-HSUN HSIEH, TAIPEI CITY (TW)

(21) Appl. No.: 19/305,762

(22) Filed: Aug. 21, 2025

Related U.S. Application Data
(60) Provisional application No. 63/685,297, filed on Aug. 21, 2024.

(51) Int. Cl. H01L 23/538; H01L 21/48; H01L 21/56; H01L 21/683; H01L 23/00; H01L 23/31; H01L 23/473; H01L 25/065; H01L 25/10; H10D 80/30

(52) U.S. Cl. CPC H01L 23/5381; H01L 21/4846; H01L 21/568; H01L 21/6835; H01L 23/3185; H01L 23/473; H01L 23/5385; H01L 25/0655; H01L 25/105; H01L 24/16; H01L 24/32; H01L 2221/68318; H01L 2224/16225; H01L 2224/32225; H01L 2224/32245; H01L 2924/37001; H10D 80/30

(57) ABSTRACT

A panel-level semiconductor package structure is provided. The panel-level semiconductor package structure includes a panel-level substrate structure and at least one wafer-level package structure. The panel-level substrate structure has a first side and a second side opposite to the first side. The wafer-level package structure is bonded over the panel-level substrate structure. Each of the wafer-level package structures includes a first redistribution layer (RDL) over the elastomeric connector and a plurality of first semiconductor devices laterally disposed over the first RDL. A method for manufacturing a panel-level substrate structure is also provided.

### PRIORITY CLAIM AND CROSS-REFERENCE

This application claims the benefit of prior-filed U.S. provisional application No. 63/685,297, filed on Aug. 21, 2024, and incorporates by reference herein in its entirety.

### FIELD

This disclosure relates in general to a semiconductor package structure and method for manufacturing thereof, and more particularly, the semiconductor package structure is a panel-level semiconductor package structure having a panel-level substrate structure and at least one wafer-level package structure bonded over the panel-level substrate structure.

### BACKGROUND

High-end artificial intelligence (AI), as well as high-performance computing (HPC) and data center applications, rely heavily on massively parallel computation to process enormous volumes of data. These tasks are enabled by the deployment of cutting-edge graphics processing units (GPUs) in combination with high-bandwidth memory (HBM) DRAM stacks. To further enhance AI system performance, the integration of a higher number of GPUs and a correspondingly higher number of HBMs becomes important. Such configurations require either larger interposers, larger substrates and/or larger computational platforms involving heterogeneous integration of large interposer and large substrate technologies, which will be increasingly implemented via panel-level fan-out (FO) packaging technologies to achieve higher utilization and throughput in comparison with their wafer-level counterparts.

At present, the largest FO substrate available is a wafer-sized FO interposer larger than 200 mm×200 mm in size, utilized in Tesla's Dojo training tile for advanced, next-generation data center infrastructure. In contrast, the most sizable silicon interposer, specifically 2.5D interposer used in TSMC's CoWoS-S(Chip-on-Wafer-on-Substrate-S) technology, is currently manufactured at dimensions equivalent to 3.3 times the size of an extreme ultraviolet (EUV) reticle, translating to roughly 53 mm×53 mm. Going forward, in order to accommodate more GPUs and HBMs, the size of these interposers will continue to scale up and may approach full wafer dimensions and even beyond by the year 2027. Typically, both FO and silicon interposers are fabricated using wafer-level processing techniques, which involve the use of 12-inch (300 mm) silicon wafers and 12-inch carriers. Compared to panel-level processes, wafer-level processes suffer from lower utilization and throughput assuming panel-level and wafer-level processes achieve technology parity.

To enable continuing scaling AI system performance, there is a growing and urgent need to develop ultra-large fine-line/space (L/S) interposers that extend beyond conventional wafer dimensions. Referring to FIG. 1, it can be seen that the panel sizes utilized in PCB (printed circuit board; or analogously organic laminate substrate) and glass panel processing are far larger than 300 mm wafers, and there exists a large assortment of panel sizes, both of which lead to higher utilization and throughput assuming again wafer-level and panel-level technologies are on par. Regarding panel-level FO, a panel size of 510 mm×515 mm (see FIG. 1) similar to what is used in PCB processing is common.

Currently, the minimum achievable fine-line/space (L/S) resolution in wafer-based FO structures is about 2 μm/2 μm (assuming a dielectric such as a photosensitive polyimide, PI, is used), and this figure is expected to shrink further to approximately below 2 μm/2 μm or even 1 μm/1 μm with ongoing process advancements. While wafer-based structures benefit from established infrastructure and existing ultra-fine-line/space equipment, the total available surface area of a 300 mm wafer limits its scalability as the interposer size, whether it be based on silicon or FO, goes beyond the 3.3× reticle size (not to mention beyond wafer sizes).

On the other hand, the minimal L/S in panel-level PCB substrate processing is greater than about 8 μm/8 μm (assuming the use of Ajinomoto Build-up Film (ABF)), although future technological improvements are aiming to reduce it to approximately 6 μm/6 μm or even as low as 2 μm/2 μm. For panel-level glass (i.e., glass-core) substrate processing, the L/S can be about 4 μm/4 μm based on the PI dielectric. Thanks to new technology advancements in recent years, new technologies (covering new panel-level equipment and dielectrics) allowing one to scale panel-level related L/Ss down to 1 μm/1 μm and even beyond are now available. This provides a golden opportunity for panel-level processes to achieve technology parity with their wafer-level counterparts while enabling higher utilizations and throughputs.

Referring to FIG. 2, which illustrates substrate utilization in a conventional 12-inch wafer, it is observed that the efficiency of silicon substrate use reduces significantly as the dimensions of the silicon or FO interposer in advanced packages scale (i.e., increase). For instance, wafer-level processing of a 53 mm×53 mm silicon interposer results in a silicon substrate utilization of only about 68%. After technology parity is achieved with wafer-level packaging (WLP), panel-level packaging (PLP) with a large assortment of panel sizes to choose from presents a breakthrough in substrate utilization and a far higher throughput as a large panel covers an area, which is many times that of a 300 mm wafer.

When it comes to panel-level interposer processing for future AI and HPC applications, there exist two primary substrate candidates: molding compound substrate for FO and glass (i.e., glass-core) substrate, both of which have a thermal conductivity (TC) on the order of 1 W/m·K, far lower than that of silicon used in 2.5D/COWOS-S interposers. (Note: Based on new developments, panel-level silicon may become a reality in the future.) This large disparity underscores the thermal limitations of non-silicon substrate materials when used in high-performance interposer designs for AI and HPC applications. That said, despite its relatively low TCs, glass substrates present several critical advantages over molding compounds, particularly when targeting ultra-large packaging formats. Compared to molding compounds, glass exhibits superior mechanical strength and better warpage control, and stands to support fine-line/space (IS) patterning due to its flatness. These attributes are vital for achieving high-density, high-layer-count interconnects in advanced packages. For these reasons, glass is increasingly viewed as a strong candidate for PLP implementation, where interposer sizes will eventually approach or exceed the processing area of conventional 300 mm wafers.

In the context of modern AI and HPC systems where GPU power continues to rise dramatically, effective heat removal will become increasingly more challenging. Today, a high-power GPU used in NVIDIA's GB200 2.5D package dissipates 1200 W/chip, and its cooling is achieved through a cold plate and a heat spreader attached to the backside of the GPU (and also to the backside of lower-power HBMs). A high-TC interposer substrate will allow cooling to proceed not only from the conventional or traditional chip backside, but also from the front-side, i.e., from the chip's frontend-of-line (FEOL) side or equivalently from the interposer side, thereby enabling higher-power GPUs to be implemented for enhanced system performance.

### SUMMARY

It is one aspect of the present disclosure to provide a panel-level semiconductor package structure. The panel-level semiconductor package structure includes a panel-level substrate structure, an optional elastomeric connector, and at least one wafer-level package structure. The panel-level substrate structure has a first side and a second side opposite to the first side. The optional elastomeric connector is disposed over the first side of the panel-level substrate structure. The wafer-level package structure is connected to the elastomeric connector. The wafer-level package structure also includes a first redistribution layers (RDL) over the elastomeric connector and a plurality of first semiconductor devices laterally disposed over the first RDL.

It is another aspect of the present disclosure to provide a panel-level semiconductor package structure. The panel-level semiconductor package structure includes a panel structure, an array of wafer-level package structures, and a stitching structure. The panel structure has a first side and a second side opposite to the first side, wherein the panel structure includes a rectangular profile from a top-view perspective. The array of wafer-level package structures is disposed over the first side of the panel structure, wherein each of the wafer-level package structures comprises a plurality of semiconductor devices having sides formed by a sawing or dicing process (i.e., semiconductor devices with cut edges). The stitching structure is located between the arrays of wafer-level package structures. The stitching structure is configured to electrically connect a plurality of first semiconductor devices in the wafer-level package structures and, optionally, a conductive structure in the panel structure.

It is yet another aspect of the present disclosure to provide a method for manufacturing a panel-level substrate structure. The method includes the following operations. A first carrier substrate with a first release layer formed on a side of the first carrier substrate is provided. A plurality of substrate units are placed over the first release layer. A space between adjacent substrate units is filled with a molding compound. A planarizing operation is performed to upper surfaces of the substrate units and an upper surface of the molding compound. A first panel-level RDL is formed over the planarized side of the substrate units. The first panel-level RDL is attached with a second release layer on a second carrier substrate. The first carrier substrate is released. A second panel-level RDL is formed over the other side of the substrate units. The second carrier substrate is released. A conductive elastomeric layer is attached to the first panel-level RDL.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates the size differences among wafers, PCB panels, and glass panels.

FIG. 2 illustrates the substrate utilization among different interposer sizes in a conventional 300 mm wafer.

FIG. 3 illustrates a cross-sectional view of a panel-level semiconductor package structure according to some embodiments of the present disclosure.

FIG. 4 illustrates a cross-sectional view of a panel-level semiconductor package structure according to some embodiments of the present disclosure.

FIG. 5 illustrates a cross-sectional view of a wafer-level package structure according to some embodiments of the present disclosure.

FIG. 6 illustrates a cross-sectional view of a panel-level semiconductor package structure according to some embodiments of the present disclosure.

FIG. 7A illustrates a cross-sectional view of a substrate unit according to some embodiments of the present disclosure.

FIG. 7B illustrates a cross-sectional view of a substrate unit according to some embodiments of the present disclosure.

FIG. 7C illustrates a cross-sectional view of a substrate unit according to some embodiments of the present disclosure.

FIG. 7D illustrates a cross-sectional view of a substrate unit according to some embodiments of the present disclosure.

FIG. 8A illustrates a cross-sectional view of a panel-level substrate structure according to some embodiments of the present disclosure.

FIG. 8B illustrates a cross-sectional view of a panel-level substrate structure according to some embodiments of the present disclosure.

FIG. 9A illustrates a cross-sectional view of a panel-level substrate structure according to some embodiments of the present disclosure.

FIG. 9B illustrates a cross-sectional view of a panel-level substrate structure according to some embodiments of the present disclosure.

FIG. 10A illustrates a cross-sectional view of a panel-level substrate structure according to some embodiments of the present disclosure.

FIG. 10B illustrates a cross-sectional view of a panel-level substrate structure according to some embodiments of the present disclosure.

FIG. 10C illustrates a cross-sectional view of a panel-level substrate structure according to some embodiments of the present disclosure.

FIG. 11 illustrates a top view of a panel-level semiconductor package structure according to some embodiments of the present disclosure.

FIG. 12A illustrates a cross-sectional view of a semiconductor structure to illustrate an example of physical redundancy according to some embodiments of the present disclosure.

FIG. 12B illustrates a cross-sectional view of a semiconductor structure to illustrate an example of physical redundancy according to some embodiments of the present disclosure.

FIG. 13 illustrates cross-sectional views of a process of manufacturing a panel-level substrate structure according to some embodiments of the present disclosure.

FIG. 14 illustrates cross-sectional views of a process of manufacturing a panel-level substrate structure according to some embodiments of the present disclosure.

FIG. 15 illustrates cross-sectional views of a process of manufacturing a panel-level substrate structure according to some embodiments of the present disclosure.

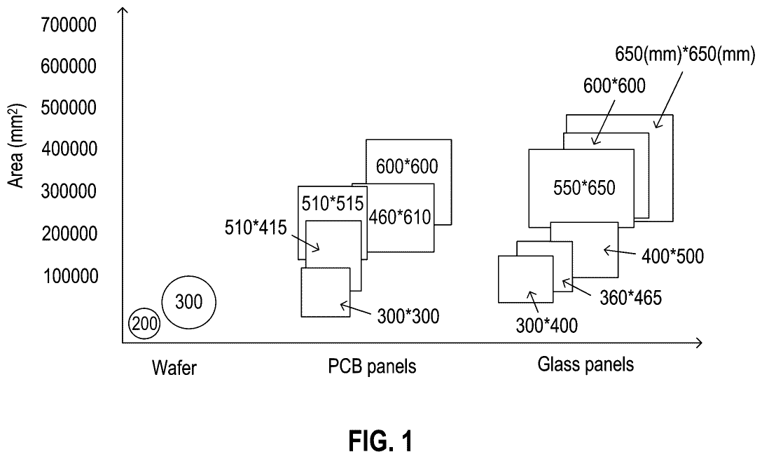

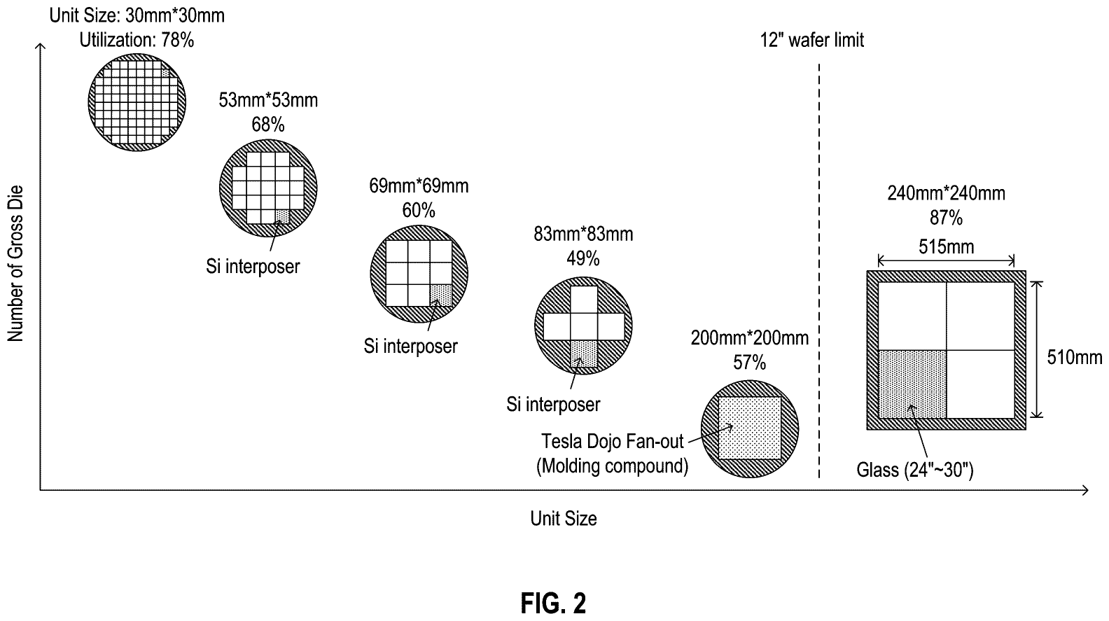

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

In some comparative embodiments, the aforementioned Tesla's Dojo training accelerator, which is based on wafer-scale embedded-die FO packaging (used to form a compute tile composing of a 5×5 grid of pre-tested known-good processors), along with Cerebras's single-die wafer-scale AI accelerator (i.e., a wafer-scale system-on-chip, SoC), ushered in the beginning of the wafer-scale computing era for unprecedented performance. These groundbreaking architectures are designed to support next-generation data centers and meet the growing demands of artificial intelligence, particularly in response to the increasing number of large language models (LLMs) and massive-scale training workloads. The present invention enables the creation of beyond-wafer-scale AI accelerators using panel-level FO processing (FOPLP), which can out-perform Tesla's Dojo training tile and Cerebras's single-die wafer-scale AI accelerator.

By leveraging rectangular panels that are significantly larger than the standard 12-inch carrier used in fan-out packaging or the 12-inch wafer used for silicon interposers and single-die wafer-scale SoC, FOPLP enables scalability in both substrate area and heterogeneous functional integration. With appropriately selected panel dimensions, such as integer multiples of the FO substrate, interposer or SoC dimensions, PLP can achieve optimal panel utilization while simultaneously addressing the dual challenges of scaling beyond wafer size and maintaining high substrate utilization.

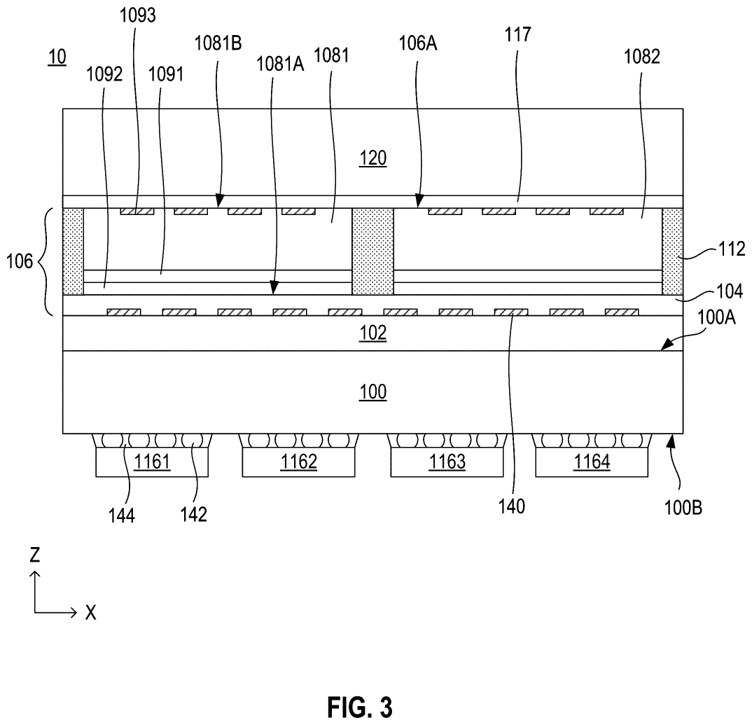

Referring to FIG. 3, which illustrates a panel-level semiconductor package structure 10 according to some embodiments of the present disclosure. In some embodiments, the panel-level semiconductor package structure 10 is created through a panel-level technology. In some embodiments, the panel-level semiconductor package structure 10 includes a panel-level substrate structure 100, an optional elastomeric connector 102, and at least one wafer-level package structure 106. The panel-level substrate structure 100 has a first side 100A and a second side 100B opposite to the first side 100A. The elastomeric connector 102 is over the first side 100A of the panel-level substrate structure 100. The wafer-level package structures 106 are bonded over the elastomeric connector 102.

In some embodiments, each of the wafer-level package structures 106 includes a first redistribution layer (RDL) 104 and a plurality of first semiconductor devices (1081, 1082, etc.). In some embodiments, the first RDL 104 is disposed over the elastomeric connector 102. In some embodiments, the plurality of first semiconductor devices 1081 and 1082 are laterally disposed over the first RDL 104. In some embodiments, the wafer-level package structures 106 further includes a first molding compound 112 over the first RDL 104 and laterally surrounding the first semiconductor devices 1081 and 1082.

In some embodiments, the first semiconductor devices 1081 and 1082 are wafer-scale SoC structures. Generally, a wafer-scale SoC structure refers to an architecture in which a silicon wafer is used as a single, integrated chip, rather than being diced into individual dies. These wafer-scale SoC structures may incorporate thousands of processing cores, large on-chip memory blocks, and high-bandwidth interconnect networks. They may enable ultra-low latency communication between cores, massive parallelism, and reduced packaging complexity, thereby collectively achieving significant improvements in performance and energy efficiency for large-scale AI and HPC workloads.

In some embodiments, the first semiconductor device 1081 includes a first side 1081A and a second side 1081B opposite to the first side 1081A. The first side 1081A may serve as the active surface, where a FEOL structure 1091 and a back-end-of-line (BEOL) structure 1092 are formed. Each first semiconductor device 1081 may further include a plurality of conductive pads 1093 on the second side 1081B. In some embodiments, the conductive pads 1093 are backside-cooling fins, backside power delivery network (BSPDN), power vias and/or nano-pillars, formed on the second side 1081B. In other embodiments, the conductive pads 1093 are thermal vias used to transfer heat away from the first semiconductor devices 1081.

In some embodiments, the thicknesses of the first semiconductor devices 1081 and 1082 within the wafer-level package structure 106 are substantially uniform (e.g., these thicknesses can be the same). These semiconductor devices may be leveled with each other such that their second sides 1081B are coplanar. The first semiconductor devices 1081 and 1082 may be covered by a heat dissipation feature 120. In some embodiments, the heat dissipation feature 120 is positioned in proximity to the upper side 106A of the wafer-level package structure 106. The heat dissipation feature 120 may be implemented comprising a cold plate, a heat spreader, thermal interface materials 117 (TIMs), and/or an impinging-flow liquid cooling structure. Generally, impinging-flow liquid cooling structures utilize high-speed liquid jets that are directed to strike the surfaces of the heat-generating component, which can be the backside cooling fin structure on the second side 1081B. This configuration significantly enhances heat transfer by disrupting the thermal boundary layer at the surface. For example, in AI accelerators or wafer-scale chips where localized hot spots can exceed thermal design limits, an impinging flow structure enables efficient heat removal from targeted regions.

That is, the wafer-level package structures 106 within a panel-level semiconductor package structure can be uniformly assembled with the heat dissipation feature 120, for example, under a panel-level heat dissipation strategy. In some embodiments, the heat dissipation feature 120 is a high-thermal-conductivity (HTC) heat spreader having a thermal conductivity (TC) greater than approximately 1,500 W/m·K (e.g., a diamond-based heat spreader), or at least having a TC approximately equal to or greater than 321 W/m·K (e.g., an aluminum nitride-based heat spreader).

In some embodiments, the heat dissipation feature 120 may be attached to the upper side 106A of the wafer-level package structure 106. For instance, the heat dissipation feature 120 may include a mesh-like pattern that thermally contacts specific high-temperature regions within the wafer-level package structure 106, such as hot spots located in the semiconductor chips (e.g., the first semiconductor devices 1081 and 1082). In other embodiments, the shape of the heat spreader may vary depending on the required thermal efficiency or specific cooling demands of the wafer-level package structure 106.

The wafer-level package structure 106, which is mounted on the panel-level substrate structure 100, serves as a high-performance computing unit within a system-level package structure designed for AI applications. In some embodiments, the components within the wafer-level package structure 106 may be fabricated by advanced integrated circuit (IC) manufacturing facilities, such as leading-edge semiconductor foundries and OSAT (outsourced assembly and test) providers. For example, the wafer-level package structure 106 may include advanced-IC-node logic structures (e.g., logic dies or chips), high-bandwidth memory (HBM) devices, and, depending on the packaging technology (e.g., 2.5D or 3D integration), may further comprise partial or complete silicon interposers with through-silicon vias (TSVs), and/or hybrid bonding structures manufactured by OSATs or advanced IC foundries. These structures essentially leverage the wafer-level manufacturing capabilities of advanced IC foundries and OSATs to deliver high-density integration.

In some embodiments of the present disclosure, the wafer-level package structure is heterogeneously integrated with a mature-process product, namely a panel structure derived from the LCD industry. For instance, the wafer-level package structure 106 may be integrated within an LCD manufacturing environment involving panel-level oxide/nitride/organic dielectric/copper (Cu) interconnection processes. Therefore, in some embodiments, the resulting panel-level semiconductor package structure is a heterogeneously integrated product. One side of the wafer-level package structure 106 may include ultra-fine-L/S features comparable to those achievable using advanced IC foundry interposer processes, while the other side may include coarser-L/S features created using FOPLP processes based primarily on organic dielectrics.

Still referring to FIG. 3, as previously described, the wafer-level package structures 106 include the first RDL 104. Based on the interface characteristics between the wafer-level package structure 106 and the panel-level substrate structure 100, the first RDL 104 can be used to interconnect the first side 1081A of the first semiconductor devices (e.g., 1081, 1082) which can be interconnected using ultra-fine-L/S processes. In some embodiments, the ultra-fine-L/S processes may involve polyimide/copper (PI/Cu) or oxide/copper (oxide/Cu) interconnection processes.

In some embodiments, the first RDL 104 can be a stitching structure or a part of a stitching structure that electrically connects the plurality of first semiconductor devices (e.g., 1081 and 1082) in the wafer-level package structures 106 and can embody one or more conductive structures, such as TSVs for dual-side interconnection. In such embodiments, the stitching structure can include one or two RDLs, one or two BEOL structures, one or more 2D/2.5D/3D metallization structures, or combinations thereof. In some embodiments, the stitching structure may include interconnection structures including multi-layered routing structures having one or more polyimide/copper (PI/Cu) layers, one or more oxide/copper (oxide/Cu) layers, or combinations thereof. In some embodiments, the L/S of the PI/Cu RDL can be about 2 μm/2 μm, the L/S of the ABF-like/Cu RDL can be about <2 μm/2 μm and the L/S of the oxide/Cu layers can be 1 μm/1 μm or smaller.

In some embodiments, the conductive structure in the stitching structure can be built of metals other than copper (Cu) such as aluminum (Al), as well as other possible conductive metals used or may be used in semiconductor structures, for example, tungsten (W), titanium (Ti), tantalum (Ta), ruthenium (Ru), cobalt (Co), nickel (Ni), molybdenum (Mo), Osmium (Os), palladium (Pd), rhodium (Rh), platinum (Pt), iridium (Ir), or the like. That is, the stitching structure refers to a stacked conductive wiring structure, which integrates the electrical connection structures required between the wafer-level package structure 106 and the panel-level substrate structure 100 into an ensemble of conductive wiring structures. This enables design flexibility and the implementation of wide-ranging L/Ss on one RDL or two RDLs to interconnect the wafer-level package structures 106 and the panel-level substrate structure 100.

In some embodiments, the elastomeric connector 102 is positioned between the wafer-level package structures 106 and the panel-level substrate structure 100, and the elastomeric connector 102 may be used to address structural challenges associated with heterogeneous integration and thermal expansion matches. For example, thermal expansion mismatch stress may occur between the wafer-level package structures 106 and the panel-level substrate structure 100, as they have different coefficients of thermal expansion (CTE). If these two structures are directly connected, the electrical contact joints may be deformed or separate during operation due to the large thermal or mechanical stresses between two large mating structures. To address this issue, the elastomeric connector 102 is used to maintain reliable electrical connections even when the contact points are distorted. In applications where joint deformations are not as large, i.e., not large enough to cause reliability issues during system operation, more conventional solder based joints may be deployed.

That is, the elastomeric connector 102 can be employed to absorb or buffer such stresses and ensure mechanical integrity during system operation. In some embodiments, the elastomeric connector 102 may include an anisotropic elastomeric connector (AEC), or other suitable structures. For instance, an AEC typically consists of a flexible polymer matrix embedded with vertically aligned conductive particles, such as silver-coated spheres. When the AEC layer is heated and compressed during assembly, these conductive spheres are pressed into vertical alignment, forming electrical pathways in the z-direction (vertical), but do not contact adjacent spheres on the sides, thus maintaining electrical isolation in the x- and y-directions. The elastomeric connector layer, made of polymer material, can be heated and cured to bond and form the electrical connections between the wafer-level package structures 106 and the panel-level substrate structure 100. Accordingly, the elastomeric connector 102 enables high-density, pressure-contact interconnects between opposing structures while accommodating mechanical stresses, ensuring both electrical performance and mechanical reliability in heterogeneous integration applications.

In some embodiments, a plurality of bonding pads 140 can be formed in the RDL 104 (or the stitching structure) and in contact with the elastomeric connector 102. In some embodiments, the plurality of bonding pads 140 are at least partially embedded in the first RDL 104. In other embodiments, the plurality of bonding pads 140 protrude from the surface of the first RDL 104.

The panel-level substrate structure 100 is a substrate structure that is larger in area than the wafer-level package structure 106. In some embodiments, the panel-level substrate structure 100 may include a PCB panel or a glass panel. In some embodiments, the panel-level substrate structure 100 is a thermally enhanced ultra-large substrate for power delivery and signaling, and therefore the panel-level substrate structure 100 may include conductive structures for electrical connection. Moreover, in some embodiments, the panel-level substrate structure 100 can have a plurality of substrate units physically separated from each other, and an interconnect bridge structure can be used to electrically or optically connect adjacent substrate units. Embodiments regarding the panel-level substrate structure having the plurality of substrate units and/or the conductive structures will be described later.

Still referring to FIG. 3, in some embodiments, a plurality of second semiconductor devices 1161, 1162, 1163, 1164, etc. can be mounted on the second side 100B of the panel-level substrate structure 100. The second semiconductor devices can be active components, or passive components in the panel-level semiconductor package structure. In some embodiments, the second semiconductor devices may include memory dies, voltage regulator dies, data I/O dies, other types of peripheral function devices, or the like. In some embodiments, the second semiconductor devices may contain active components such as CPUs, GPUs, NPUs, FPGAs, etc. In some embodiments, the second semiconductor devices may include transceivers, and optical interconnects. In some embodiments, the second semiconductor devices are mounted on the second side 100B of the panel-level substrate structure 100 by a plurality of micro bumps, solder bumps 142, wherein these bumps 142 can further be surrounded by an encapsulate material 144. In other embodiments, the second semiconductor devices are bonded on the second side 100B of the panel-level substrate structure 100 using copper hybrid bonds surrounded by dielectric materials. However, the present disclosure is not limited to these techniques for mounting the second semiconductor devices on the second side 100B of the panel-level substrate structure 100.

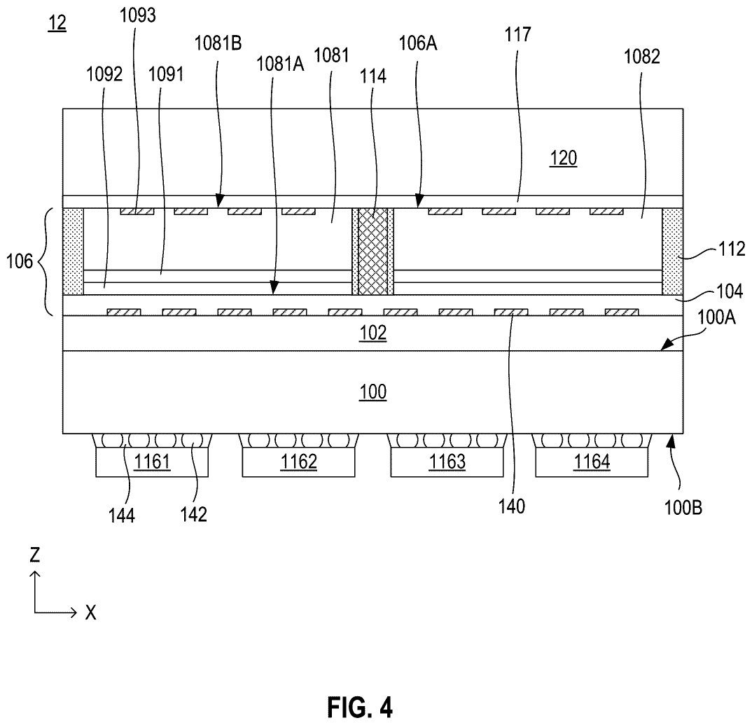

Referring to FIG. 4, which illustrates a cross-sectional view of a panel-level semiconductor package structure 12 according to some embodiments of the present disclosure. As shown in FIG. 4, the wafer-level package structure 106 may include a first bridge structure 114 located between two adjacent first semiconductor devices (e.g., 1081 and 1082) and penetrating the first molding compound 112. In some embodiments, the first bridge structure 114 can be an interconnect bridge that is optionally located between the semiconductor devices in the wafer-level package structure 106. In some embodiments, the first bridge structure 114 can be made using advanced IC BEOL processes or using advanced IC BEOL and FEOL processes wherein the BEOL L/Ss are beyond the reach of FOPLP. The first bridge structure 114 can optionally contain ultra-fine-pitch contact pads over a limited area on its front-side or its first side 1081A to facilitate interconnection of high-density circuits between two adjoining first semiconductor devices (e.g., the first semiconductor devices 1081 and 1082). By limiting high-density interconnects to a limited area of the first bridge structure 114, one can achieve higher stitching yields using the first bridge structure 114. The first bridge structure 114 can contain through vias which traverse the thickness of the structure and serve as thermal vias. In some embodiments, whether the first bridge structure 114 is used between the two adjoining first semiconductor devices depends on the sizes of the first bridge structure 114 and the space between the two adjoining first semiconductor devices.

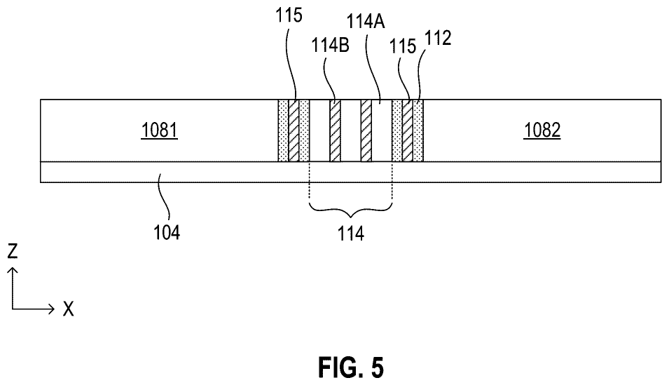

Referring to FIG. 5, which illustrates a cross-sectional view of the first bridge structure 114 according to some embodiments of the present disclosure. As shown in FIG. 5, the first bridge structure 114 can be a bridge interposer that is substantially leveled with the two adjacent first semiconductor devices 1081 and 1082. In some embodiments, the first bridge structure 114 includes one or more of TSV 114B traversing the thickness of the bridge substrate 114A which can a silicon substrate or can be based on other suitable substrate materials including a high-TC material. In some embodiments, there exist TMVs (through-mold vias) 115 laterally surrounded by the first molding compound 112 but electrically isolated from the first bridge structure 114. In some embodiments, one side of the first bridge structure 114 may include the first RDL 104. In other embodiments, the first bridge structure 114 may be free from having TSVs 114B.

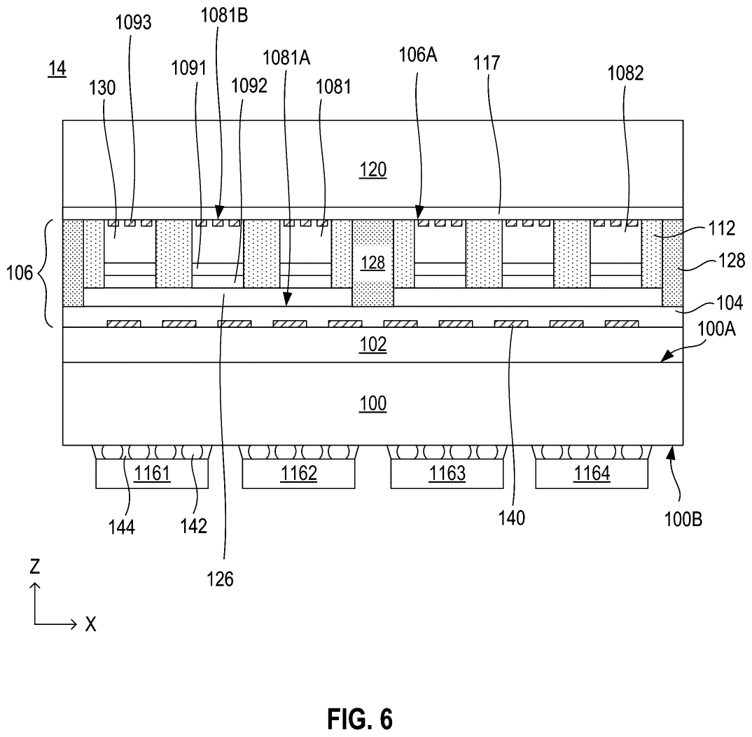

Referring to FIG. 6, which illustrates a cross-sectional view of a panel-level semiconductor package structure 14 according to some embodiments of the present disclosure. As shown in FIG. 6, the first semiconductor devices 1081 and 1082 are wafer-scale fan-out structures, and a plurality of second RDLs 126 can be formed between the first semiconductor devices 1081 and 1082 and the first RDL 104. In some embodiments, each second RDL 126 is in contact with a group of semiconductor dies 130 in the first semiconductor devices. In some embodiments, the first molding compound 112 laterally surrounds the semiconductor dies 130 in each group of semiconductor dies in the semiconductor device (e.g., the first semiconductor device 1081 or 1082); and a second molding compound 128 is laterally surrounding each group of semiconductor dies 130. The second molding compound 128 also laterally surrounds the first semiconductor devices 1081 and 1082. In some embodiments, a thickness of the second molding compound 128 is greater than a thickness of the first molding compound 112.

As aforementioned, the panel-level substrate structure 100 can include a plurality of substrate units that are physically separated from each other, and an interconnect bridge structure can be used to electrically or optically connect adjacent substrate units. This form of tiled substrates may help achieve high panel-level substrate structure yields. On the other hand, if the wafer-level package structure 106 requires more efficiently heat dissipation, a heat spreader in a mesh form may be disposed between the wafer-level package structure 106 and the panel-level substrate structure 100.

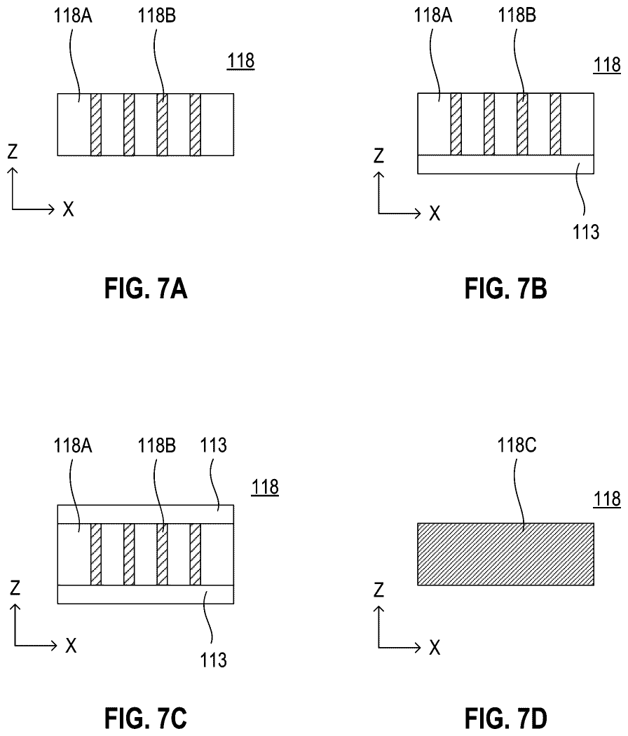

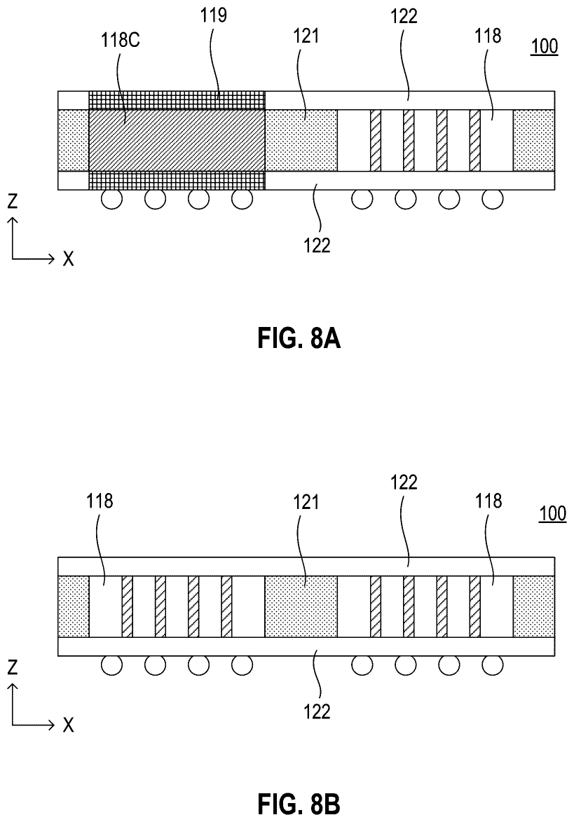

Referring to FIGS. 7A to 7D, and FIGS. 8A and 8B, which illustrate the different types of substrate units 118 that can be included in the panel-level substrate structure 100. In some embodiments, the substrate units 118 may include passive components, active dies, substrates (organic or inorganic), or interposers. In some embodiments, the substrate units 118 may be either a partial interposer or a complete interposer, depending on whether the substrate units 118 have two RDLs on both sides thereof. In some embodiments, the substrate units 118 may be either a partial die or a complete die, depending on whether the substrate units 118 have two RDLs on both sides thereof. In some embodiments, the substrate units 118 may be interconnect bridges, fan-out interposers, passive-components-embedded substrates, high-TC (HTC) heat spreaders, embedded-active-die substrates, embedded-die fan-outs, wafer-scale SoCs, the like or combinations thereof.

Referring to FIG. 7A, in some embodiments, the substrate unit 118 may be a partial interposer that includes a silicon substrate 118A and a plurality of TSVs 118B traversing the thickness of the silicon substrate 118A. Referring to FIG. 7B, in some embodiments, the substrate unit 118 may be a partial die that includes the silicon substrate 118A, a plurality of TSVs 118B traversing the thickness of the silicon substrate 118A, and a third RDL 113 formed on one side of the silicon substrate 118A. Referring to FIG. 7C, in some embodiments, the substrate unit 118 may be a complete interposer or a complete die that includes the silicon substrate 118A, a plurality of TSVs 118B traversing the thickness of the silicon substrate 118A, and two third RDLs 113 formed on two opposite sides of the silicon substrate 118A. In some embodiments, the third RDL 113 may include multi-layered interconnection structures based on PI/Cu, ABF or ABF-like/Cu, oxide/Cu or combinations thereof. In some embodiments, the L/S of the oxide/Cu layers within the panel-level substrate structure 100 can be less than 1 μm/1 μm, the L/S of the PI/Cu layers can be about 2 μm/2 μm or smaller, and the L/S of the ABF/Cu layers can be greater than about 10 μm/10 μm, and the L/S of the ABF-like/Cu layers can be 2 μm/2 μm or less depending the patterning technology and material used.

Referring to FIG. 7D, in some embodiments, the substrate unit 118 may include a heat spreader 118C. The heat spreader 118C can be positioned directly under one of the first semiconductor devices in the wafer-level package structure to enhance heat dissipation efficiency. In some embodiments, the heat spreader 118C, used as a thermal enhancement portion, may have a TC substantially greater than that of silicon.

In some embodiments, other materials can be used in the substrate unit 118 to replace the silicon substrate 118A in the aforementioned examples. For instance, in addition to silicon, the material of the substrate unit 118 may include glass, SiC, AlN, diamond, BN, BAs, the like, or their combinations. In some embodiments, the substrate unit 118 may include HTC layered structures such as Si/AlN, Si/Diamond, SiC/Diamond, or the like. In some embodiments, the substrate unit 118 may include composites with HTC fillers. In some embodiments, the substrate unit 118 may include a molding compound.

FIGS. 8A and 8B illustrate examples in which the panel-level substrate structure 100 includes substrate units 118 that are physically separated from each other, or includes substrate units 118 that are physically separated from each other with at least one of the substrate units 118 serving as a heat spreader (e.g., 118C). In some embodiments, at least one side of the panel-level substrate structure 100 may include a fourth RDL 122 that is electrically connected to, or in contact with, the substrate units 118 within the panel-level substrate structure 100. In some embodiments, the substrate units 118 can be laterally surrounded by a molding compound 121.

As shown in FIG. 8A, when the heat spreader 118C is used in the panel-level substrate structure 100, a plurality of thermal vias 119 can be formed on the panel-level substrate structure 100 which are thermally coupled with the heat spreader 118C. In some embodiments, the thermal vias 119 are formed in the fourth RDL 122. In some embodiments, the height of the thermal vias 119 is substantially identical to the thickness of the fourth RDL 122.

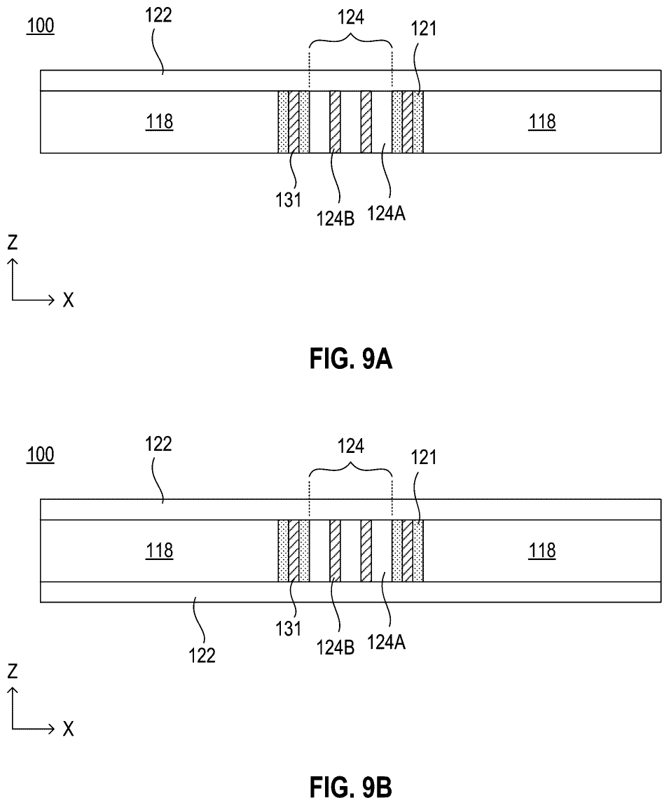

Referring to FIGS. 9A and 9B, in some embodiments, the panel-level substrate structure 100 may include a second bridge structure 124 substantially leveled with the adjacent substrate units 118. Like the first bridge structure 114 shown in FIG. 5 in the aforementioned embodiments, the second bridge structure 124 can be a bridge interposer that substantially levels with the two adjacent substrate units 118. In some embodiments, the second bridge structure 124 includes one or more of TSV 124B traversing the thickness of the second bridge substrate 124A which can a silicon substrate. In some embodiments, there exist two TMVs 131 laterally surrounded by the molding compound 121 but electrically isolated from the second bridge structure 124. In some embodiments, one side of the second bridge structure 124 may include the fourth RDL 122. In other embodiments, two sides of the second bridge structure 124 may include the fourth RDL 122.

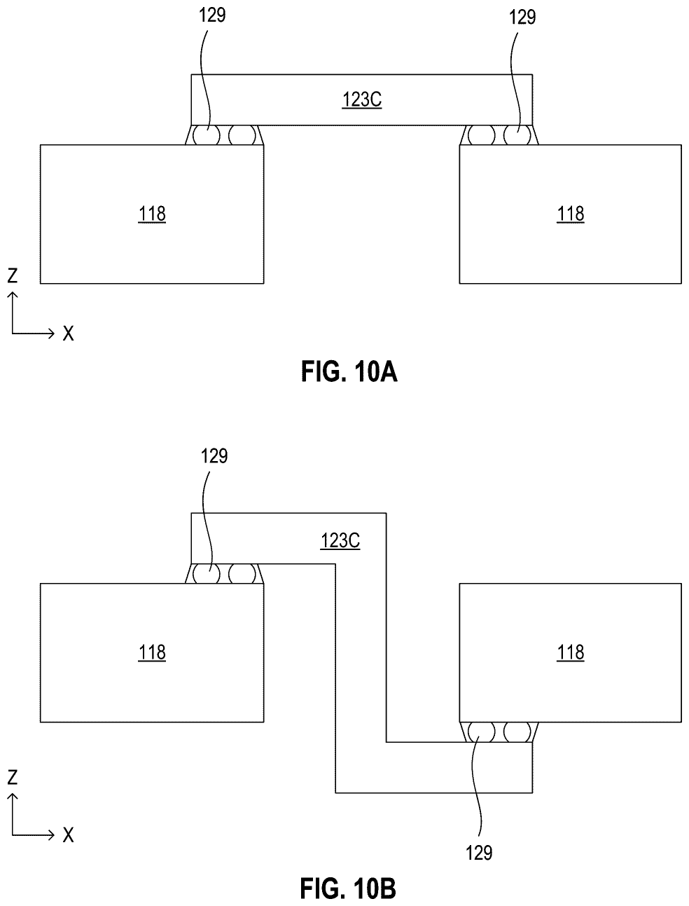

Referring to FIGS. 10A to 10C, which illustrate some examples of using flexible printed circuit (FPC) 123C as an interconnect bridge structure in the panel-level substrate structure. The FPC 123C can include a film made of polyimide or other types of flexible materials. As shown in FIG. 10A, the FPC 123C can be mounted on the same side of adjacent substrate units 118, whereas in FIG. 10B, the FPC 123C can also be mounted on the opposite sides of adjacent substrate units 118, and therefore the FPC 123C is connected to the same side or opposite sides of adjacent substrate units, in different embodiments. Moreover, as shown in FIG. 10C, the FPC 123C may embody a window opening 125 and a bent lead 127 formed by a lead forming operation following the forming of the window opening 125. The bent lead 127 can extend into the window opening 125 and be in contact with the bonding structure such as surface finish, a gold bump or a micro-bump 129 exposed in the window opening 125. In some embodiments, the FPC 123C is electrically connected to adjacent substrate units 118 and/or an integrated circuit through, for example, micro-bumps (or gold bumps) 129. Generally, each of the micro-bumps 129 is encapsulated.

In some embodiments, the substrate units 118 can be interconnected by a silicon bridge using a process consisting of depositing micro-bumps and a non-conductive paste (NCP) on the silicon bridge and bonding of the bridge to the substrate units 118 using, for example, thermo-compression bonding (TCB).

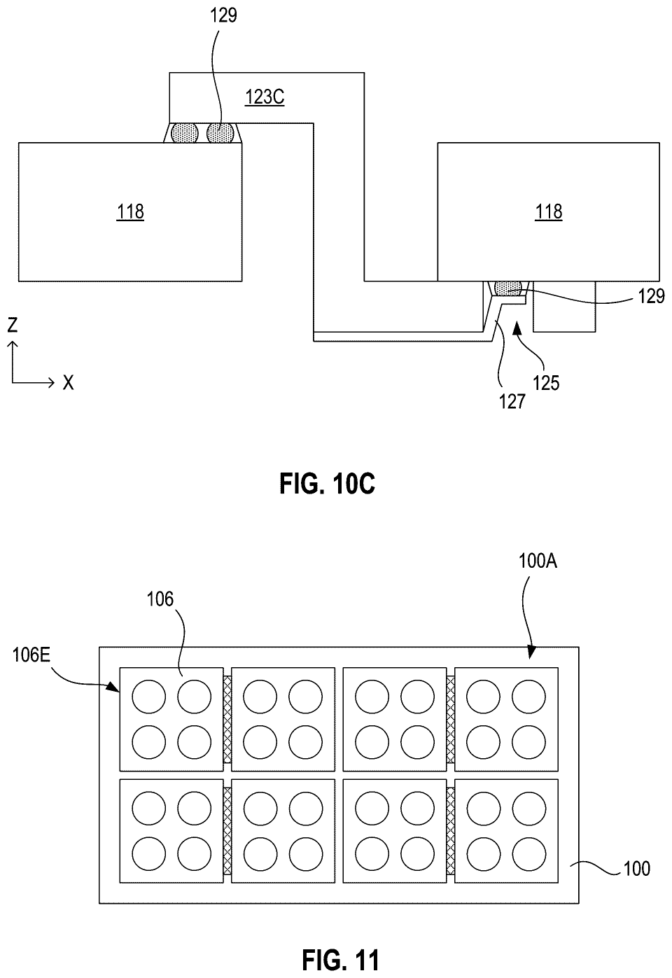

FIG. 11 illustrates a panel-level semiconductor package structure from a top-view perspective. In some embodiments, the panel-level substrate structure 100 has a rectangular profile from the top view, and an array of wafer-level package structures 106 is disposed on the first side 100A of the panel-level substrate structure 100. In some embodiments, each of the wafer-level package structures 106 includes a plurality of sides created by sawing or dicing (e.g., dicing edges 106E in FIG. 11). The dicing edges 106E of the wafer-level package structures 106 indicate that the wafer-level package structures 106 are formed from a wafer-level process. A rectangular or square (or a combination thereof) profile of each wafer-level package structure 106, as seen from the top, may enhance the area utilization efficiency when packaged on the panel-level substrate structure 100.

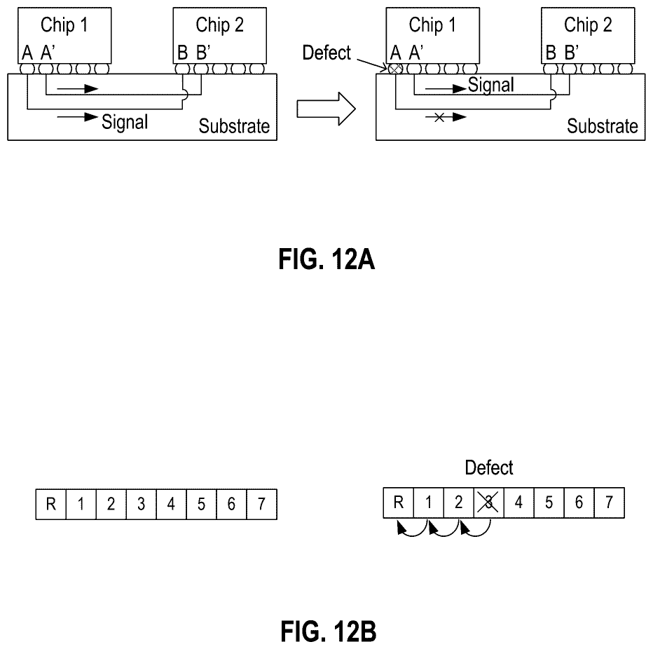

To achieve high yields in the creation of large, high-performance SoCs, FO packages or substrates using FOPLP, as well as during their subsequent assembly, various forms of redundancy are employed. As illustrated in FIG. 12A, in some embodiments, physical redundancy can be implemented at the interface level, where each signal is provided with a spare connection (e.g., A, A′; B, B′). If a defect such as an open occurs at a primary connection (e.g., A), the signal can be rerouted through its spare (A′), thereby maintaining signal integrity. This approach requires careful planning and IC-package co-design during the design phase, including the addition of spare micro-bumps for each critical signal, which increases design complexity and cost, and is typically reserved for essential signals like interface clocks. Logical redundancy is another technique, where each data bus includes one or more redundant elements. During testing, data multiplexers can be programmed to shift data from defective bits to redundant ones, restoring full functionality after repair. As shown in FIG. 12B, in some embodiments, if a defect is detected at a specific terminal (e.g., terminal 3), its function can be shifted to another terminal (e.g., terminal 2), with subsequent functions cascading accordingly, and the original function of the first terminal ultimately being assigned to a redundancy terminal. Additionally, device-level defects can be addressed through defeaturing, a method commonly used in data center and AI applications, where redundant elements are included in the design and underperforming or failed elements are disabled, particularly in caches and cores.

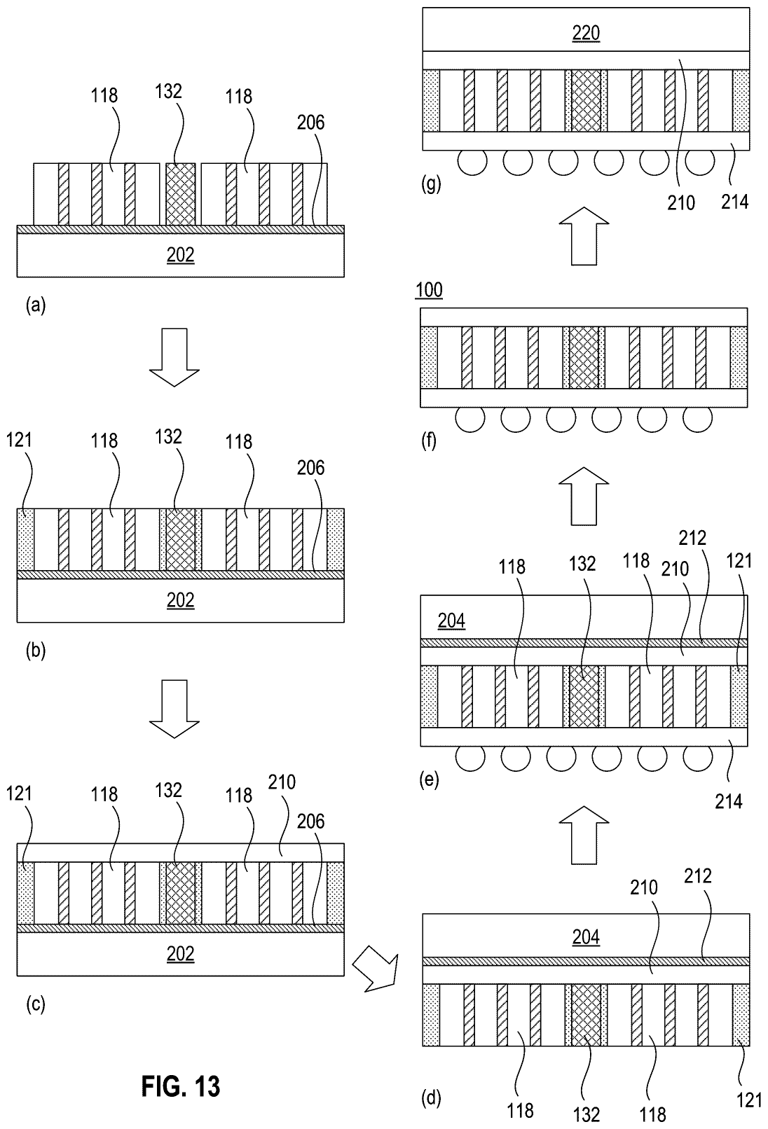

FIG. 13, including portions (a) to (g), illustrates a method for forming the panel-level substrate structure according to some embodiments of the present disclosure. As shown in FIG. 13(a), a first carrier substrate 202 is provided with a first release layer 206 formed on a side of the first carrier substrate 202. In some embodiments, the first carrier substrate 202 can be a glass substrate or another suitable substrate, depending on the required mechanical integrity and area for optimal utilization during FOPLP. In some embodiments, a plurality of substrate units 118 can be placed over the first release layer 206. The features of the substrate units 118 may refer to the embodiments previously shown in FIGS. 7A to 7D and are omitted herein for brevity. In some embodiments, a bridge structure 132 can be formed between two adjacent substrate units 118. In some embodiments, the bridge structure 132 is a bridge interposer that substantially leveled with the two adjacent substrate units 118. In some embodiments, the top portion of the bridge structure 132 is substantially coplanar with top portions of the two adjacent substrate units 118.

As shown in FIG. 13(b), in some embodiments, a space between adjacent substrate units 118 is filled with a molding compound 121. In some embodiments, a planarizing operation can be performed to upper surfaces of the substrate units 118 and an upper surface of the molding compound 121.

As shown in FIG. 13(c), in some embodiments, a first panel-level RDL 210 can be formed over one side of the substrate units 118. In some embodiments, the features of the first panel-level RDL 210 is substantially identical to the features of the fourth RDL 122 previously shown in FIGS. 8A, 8B, 9A and 9C, and are omitted herein for brevity.

In some embodiments, the first carrier substrate 202 (see FIG. 13(c)) can be removed by releasing the first release layer 206 (see FIG. 13(c)). In some embodiments, the first release layer 206 can be a thermal release tape, an UV release/adhesive layer or a thin high-Tg (glass transition temperature) die attach material that can be removed by excimer laser ablation. Then, as shown in FIG. 13(d), in some embodiments, the first panel-level RDL 210 is attached with a second release layer 212 on a second carrier substrate 204 and then the first carrier substrate 202 is released. In some embodiments, the features of the second carrier substrate 204 is substantially identical to the features of the first carrier substrate 202.

As shown in FIG. 13(e), in some embodiments, a second panel-level RDL 214 is formed over the other side of the substrate units 118. After the second panel-level RDL 214 is formed, the second carrier substrate 204 is removed by releasing the second release layer 212. In some embodiments, a plurality of conductive bumps (or conductive pads) such as solder bumps, micro-bumps or copper hybrid bonding pads can optionally be formed on the second panel-level RDL 214, before releasing the second carrier substrate 204. A plurality of conductive bumps can also be applied to the first panel-level RDL 210 if bonding pads are required in order to form 3D package structures (for example, as in the aforementioned case of Tesla Dojo).

As optionally shown in FIG. 13(g), in some embodiments, in order to address the issue of thermal-expansion-mismatch stresses during operation as in the case of beyond-wafer-scale SoC, a conductive elastomeric film 220 can be attached to the first panel-level RDL 210 assuming it contains conductive pads as stated above. Following this, the beyond-wafer-scale panel-level substrate structure 100 is ready to be packaged using the elastomeric connector for connection to the next-level substrate.

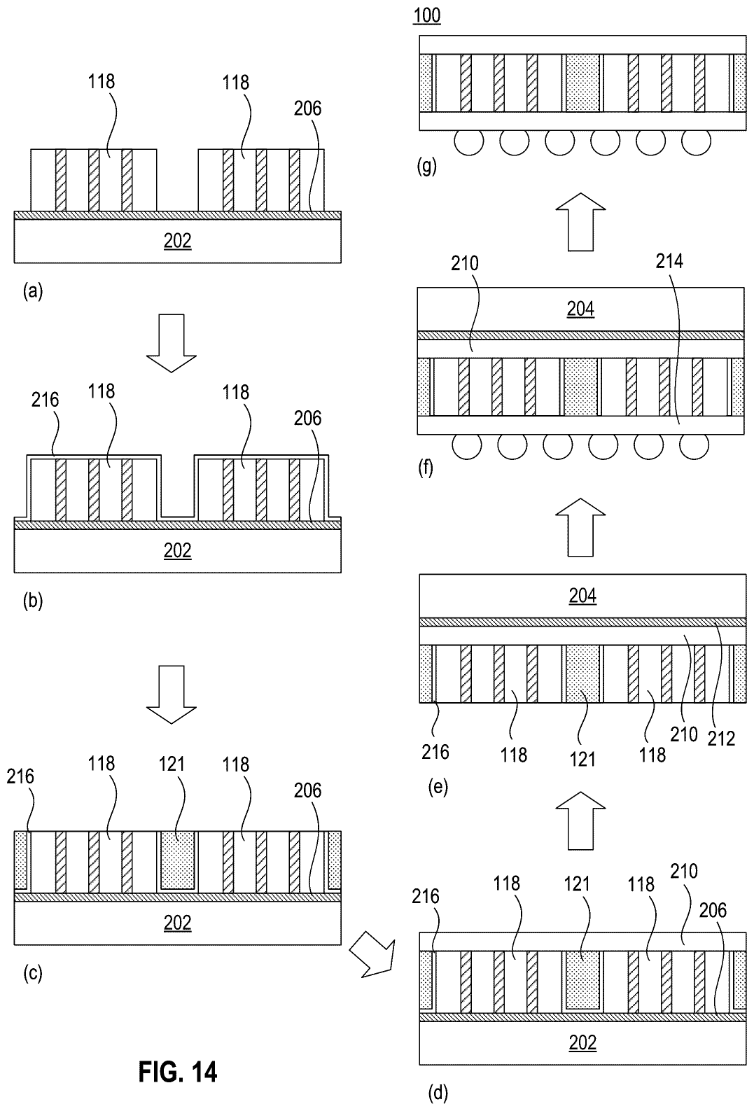

FIG. 14, including portions (a) to (g), illustrates a method for forming the panel-level substrate structure according to some embodiments of the present disclosure. In these embodiments, as shown in FIG. 14(b), a coating layer 216 is formed conformally over the upper profile of the substrate units 118 before the space between adjacent substrate units 118 is filled with a molding compound 121. In some embodiments, the coating layer 216 may be an organic coating, such as parylene or another suitable material, which covers a plurality of exposed surfaces of the substrate units 118 to prevent surface cracks during polishing. In some embodiments, the coating layer 216 is a high-quality, thin, conformal coating such as a low-deposition-temperature oxide or nitride coating whose density is higher than that of the molding compound 121. For example, the density of the coating layer 216 may be greater than that of the molding compound 121. Other operations illustrated in FIG. 14 are similar to the corresponding operations shown in FIG. 13, and the details are omitted herein for brevity.

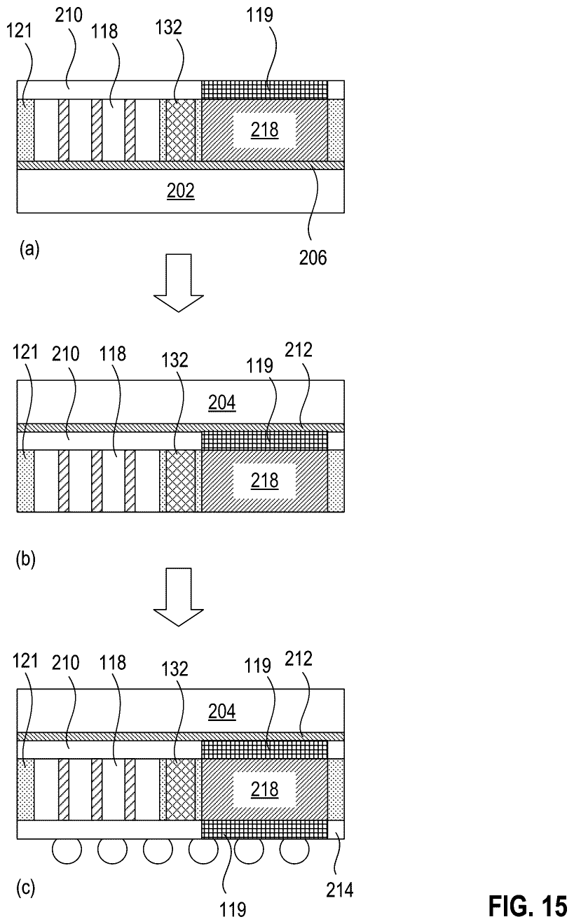

Referring to FIG. 15, including portions (a) to (c), in some embodiments, at least one of the substrate units 118 includes a heat spreader 218 having a TC substantially greater than that of silicon. In such embodiments, a plurality of thermal vias 119 can be formed in the first panel-level RDL 210 and the second panel-level RDL 214 and positioned at two sides of the heat spreader 218. These thermal vias 119 can efficiently transfer heat from a heat source into the heat spreader 218 and conduct heat away from the heat spreader 218, allowing the heat to be dissipated through the heat spreader 218. In some embodiments, additional cooling devices, such as fans and/or active coolers, may be deployed to provide more efficient cooling using the heat spreader 218 and the thermal vias during operation of the panel-level semiconductor package structure.

Though a great majority of the text above is directed toward the creation of the panel-level substrate structure 100. The methodologies, processes and structures disclosed herein are equally applicable to the creation of large interposer, SoC, and other types of substrate structures using wafer-level processes. The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A panel-level semiconductor package structure, comprising:
a panel-level substrate structure having a first side and a second side opposite to the first side; and
at least one wafer-level package structure bonded over the panel-level substrate structure, each of the wafer-level package structures comprises:
a first redistribution layer (RDL) over the panel-level substrate structure; and
a plurality of first semiconductor devices laterally disposed over the first RDL.

2. The panel-level semiconductor package structure of claim 1, wherein the wafer-level package structure further comprises:
a first molding compound over the first RDL and laterally surrounding the first semiconductor devices.

3. The panel-level semiconductor package structure of claim 2, wherein the wafer-level package structure further comprises a first bridge structure located between two adjacent first semiconductor devices and penetrating the first molding compound.

4. The panel-level semiconductor package structure of claim 1, wherein the wafer-level package structure further comprises:
a plurality of second RDLs between the first semiconductor device and the first RDL, each second RDL is in contact with a group of semiconductor dies;
a first molding compound laterally surrounding the semiconductor dies in each group of semiconductor dies; and
a second molding compound laterally surrounding each group of semiconductor dies, wherein a thickness of the second molding compound is greater than a thickness of the first molding compound.

5. The panel-level semiconductor package structure of claim 1, further comprising a heat dissipation feature in proximity to an upper side of the wafer-level package structure.

6. The panel-level semiconductor package structure of claim 1, further comprising a plurality of second semiconductor devices mounted on the second side of the panel-level substrate structure.

7. The panel-level semiconductor package structure of claim 1, further comprising an elastomeric connector over the first side of the panel-level substrate structure.

8. The panel-level semiconductor package structure of claim 1, wherein the panel-level substrate structure comprises:
a plurality of substrate units physically separated from each other; or
a plurality of substrate units physically separated from each other, and at least a substrate unit is a heat spreader, and the heat spreader is located directly under one of the first semiconductor devices in the wafer-level package structure.

9. The panel-level semiconductor package structure of claim 8, wherein the panel-level substrate structure further comprises a second bridge structure substantially leveled with the adjacent substrate units.

10. A panel-level semiconductor package structure, comprising:
a panel structure having a first side and a second side opposite to the first side, wherein the panel structure comprises a rectangular profile from a top view perspective;
an array of wafer-level package structures over the first side of the panel structure, wherein each of the wafer-level package structures comprises:
a plurality of cut edges; and
a stitching structure vertically between the panel structure and the array of wafer-level package structures, configured to electrically connect a plurality of first semiconductor devices in the wafer-level package structures and a conductive structure in the panel structure.

11. The panel-level semiconductor package structure of claim 10, wherein each of the wafer-level package structures comprises a wafer-scale SoC structure or a wafer-scale fan-out structure.

12. The panel-level semiconductor package structure of claim 10, further comprising a conductive elastomeric layer sandwiched by the stitching structure and the panel structure, wherein the stitching structure comprises an interconnect structure, wherein a line width in the interconnect structure in proximity to the array of wafer-level package structures is no greater than a line width in the interconnect structure in proximity to the panel structure.

13. The panel-level semiconductor package structure of claim 10, wherein the panel structure comprises a thermal enhancement portion having a thermal conductivity substantially greater than a thermal conductivity of silicon.

14. The panel-level semiconductor package structure of claim 13, wherein the thermal enhancement portion is located directly under one of the first semiconductor devices.

15. A method for manufacturing a panel-level substrate structure, comprising:
providing a first carrier substrate with a first release layer formed on a side of the first carrier substrate;
placing a plurality of substrate units over the first release layer;
filling a space between adjacent substrate units with a molding compound;
performing a planarizing operation to upper surfaces of the substrate units and an upper surface of the molding compound;
forming a first panel-level redistribution layer (RDL) over one side of the substrate units;
attaching the first panel-level RDL with a second release layer on a second carrier substrate;
releasing the first carrier substrate;
forming a second panel-level RDL over the other side of the substrate units;
releasing the second carrier substrate; and
attaching a conductive elastomeric layer to the first panel-level RDL.

16. The method of claim 15, further comprising:
forming a bridge structure between two adjacent substrate units before filling the space between adjacent substrate units with the molding compound.

17. The method of claim 15, further comprising:
forming a coating conformal to an upper profile of the substrate units before filling the space between adjacent substrate units with the molding compound.

18. The method of claim 17, wherein a density of the coating is different from a density of the molding compound.

19. The method of claim 15, wherein at least one of the substrate units comprises a heat spreader having a thermal conductivity substantially greater than a thermal conductivity of silicon.

20. The method of claim 19, wherein forming the first panel-level RDL further comprises forming a plurality of thermal vias in the first panel-level RDL and projectively over the heat spreader.
